(19) United States
(12) Patent Application Publication
(10) Pub. No.: US 2023/0197453 A1
(43) Pub. Date: Jun. 22, 2023

(54) STRUCTURE WITH CONDUCTIVE FEATURE FOR DIRECT BONDING AND METHOD OF FORMING SAME

(71) Applicant: ADEIA SEMICONDUCTOR BONDING TECHNOLOGIES INC., San Jose, CA (US)

(72) Inventors: Gaius Gillman Fountain, JR., Youngsville, NC (US); George Carlton Hudson, Wendell, NC (US); Pawel Mrozek, San Jose, CA (US); Cyprian Emeka Uzoh, San Jose, CA (US); Jeremy Alfred Theil, Mountain View, CA (US)

(21) Appl. No.: 18/066,159

(22) Filed: Dec. 14, 2022

Related U.S. Application Data
(60) Provisional application No. 63/291,285, filed on Dec. 17, 2021.

(51) Int. Cl. H01L 21/18; H01L 21/285; H01L 21/288

(52) U.S. Cl. CPC H01L 21/187; H01L 21/28568; H01L 21/28556; H01L 21/2885

(57) ABSTRACT

Structures and methods for direct bonding are disclosed. A bonded structure can include a first element and a second element. The first element can include a first non-conductive structure that has a non-conductive bonding surface, a cavity that extends at least partially through a thickness of the non-conductive structure from the non-conductive bonding surface, and a first conductive feature that has a first conductive material and a second conductive material over the first conductive material disposed in the cavity. A maximum grain size, in a linear lateral dimension, of the second conductive material can be smaller than 20% of the linear lateral dimension of the conductive feature. There can be less than 20 parts per million (ppm) of impurities at grain boundaries of the second conductive material.

### CROSS-REFERENCE TO RELATED APPLICATIONS

This application claims priority to U.S. Provisional Patent Application No. 63/291,285, filed Dec. 17, 2021, titled “STRUCTURE WITH CONDUCTIVE FEATURE FOR DIRECT BONDING AND METHOD OF FORMING SAME,” the entire contents of which are hereby incorporated herein by reference.

### BACKGROUND

### Field

The field relates to structures and methods for direct bonding, and in particular to hybrid direct bonding of both conductive and nonconductive features.

### Description of the Related Art

Semiconductor elements, such as integrated device dies or chips, may be mounted or stacked on other elements. For example, a semiconductor element can be mounted to a carrier, such as an interposer, a reconstituted wafer or element, etc. As another example, a semiconductor element can be stacked on top of another semiconductor element, e.g., a first integrated device die can be stacked on a second integrated device die. Each of the semiconductor elements can have conductive pads for mechanically and electrically bonding the semiconductor elements to one another.

There are many advantages to directly bonding elements together, without intervening adhesives, such as solder. However, direct hybrid bonding of both conductive features and nonconductive field regions can be challenging. Accordingly, there is a continuing need for improved methods for forming the conductive features, such as conductive pads, for use in direct bonding.

### BRIEF DESCRIPTION OF THE DRAWINGS

Specific implementations will now be described with reference to the following drawings, which are provided by way of example, and not limitation.

FIG. 1A is a schematic cross-sectional side view of two elements prior to direct hybrid bonding.

FIG. 1B is a schematic cross-sectional side view of the two elements shown in FIG. 1A after direct hybrid bonding.

FIG. 2A is a cross sectional scanning electron microscope (SEM) image of two relatively small grain conductive features that are bonded to one another.

FIG. 2B is a cross sectional SEM image of a set of conductive features that are bonded to one another and another set of conductive features that are not bonded to one another.

FIG. 2C is a cross sectional SEM image of two fine copper pads that include a large amount of impurities that are bonded to one another only in small areas.

FIGS. 3A to 3E illustrate various steps of a manufacturing process of manufacturing a bonded structure according to an embodiment.

FIGS. 4A to 4F illustrate various steps of a manufacturing process of manufacturing a bonded structure according to another embodiment.

FIG. 5 is an image generated to schematically illustrate a conductive feature 42 that includes a first conductive material 36 and a second conductive material 38 according to an embodiment.

FIG. 6 is an image generated to schematically illustrate a conductive feature 62 that includes a first conductive material 36 and a second conductive material 38 according to another embodiment.

### DETAILED DESCRIPTION

The present disclosure describes methods of forming conductive features with smaller grains at or near a bonding surface and larger grains under below the smaller grains. Such conductive features with differently sized grains can be advantageous for direct metal bonding, such as direct hybrid bonding. For example, two or more semiconductor elements (such as integrated device dies, wafers, etc.) may be stacked on or bonded to one another to form a bonded structure. Conductive contact pads of one element may be electrically connected to corresponding conductive contact pads of another element. Any suitable number of elements can be stacked in the bonded structure. The methods and bond pad structures described herein can be useful in other contexts, as well.

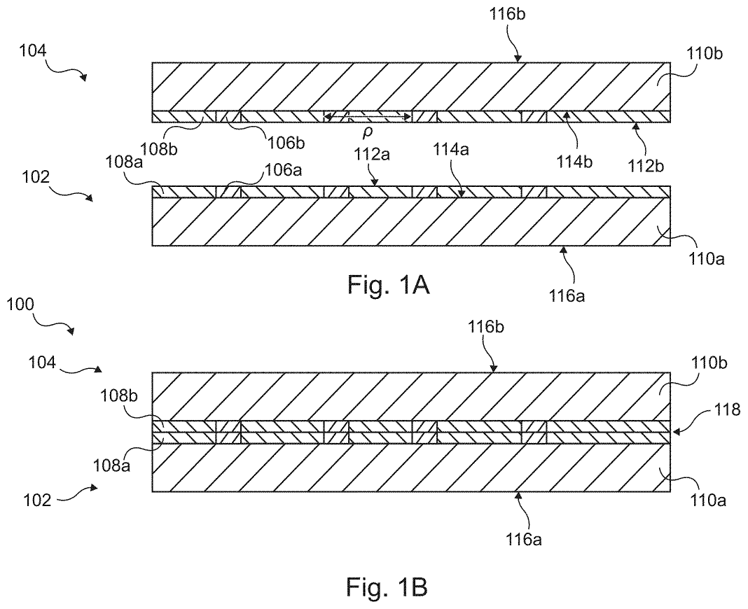

Various embodiments disclosed herein relate to directly bonded structures in which two or more elements can be directly bonded to one another without an intervening adhesive. FIGS. 1A and 1B schematically illustrate a process for forming a directly hybrid bonded structure without an intervening adhesive according to some embodiments. In FIGS. 1A and 1B, a bonded structure 100 comprises two elements 102 and 104 that can be directly bonded to one another at a bond interface 118 without an intervening adhesive. Two or more microelectronic elements 102 and 104 (such as semiconductor elements, including, for example, integrated device dies, wafers, passive devices, individual active devices such as power switches, etc.) may be stacked on or bonded to one another to form the bonded structure 100. Conductive features 106a (e.g., contact pads, exposed ends of vias (e.g., TSVs), or a through substrate electrodes) of a first element 102 may be electrically connected to corresponding conductive features 106b of a second element 104. Any suitable number of elements can be stacked in the bonded structure 100. For example, a third element (not shown) can be stacked on the second element 104, a fourth element (not shown) can be stacked on the third element, and so forth. Additionally or alternatively, one or more additional elements (not shown) can be stacked laterally adjacent one another along the first element 102. In some embodiments, the laterally stacked additional element may be smaller than the second element. In some embodiments, the laterally stacked additional element may be two times smaller than the second element.

In some embodiments, the elements 102 and 104 are directly bonded to one another without an adhesive. In various embodiments, a non-conductive field region that includes a non-conductive or dielectric material can serve as a first bonding layer 108a of the first element 102 which can be directly bonded to a corresponding non-conductive field region that includes a non-conductive or dielectric material serving as a second bonding layer 108b of the second element 104 without an adhesive. The non-conductive bonding layers 108a and 108b can be disposed on respective front sides 114a and 114b of device portions 110a and 110b, such as a semiconductor (e.g., silicon) portion of the elements 102, 103. Active devices and/or circuitry can be patterned and/or otherwise disposed in or on the device portions 110a and 110b. Active devices and/or circuitry can be disposed at or near the front sides 114a and 114b of the device portions 110a and 110b, and/or at or near opposite backsides 116a and 116b of the device portions 110a and 110b. Bonding layers can be provided on front sides and/or back sides of the elements. The non-conductive material can be referred to as a non-conductive bonding region or bonding layer 108a of the first element 102. In some embodiments, the non-conductive bonding layer 108a of the first element 102 can be directly bonded to the corresponding non-conductive bonding layer 108b of the second element 104 using dielectric-to-dielectric bonding techniques. For example, non-conductive or dielectric-to-dielectric bonds may be formed without an adhesive using the direct bonding techniques disclosed at least in U.S. Pat. Nos. 9,564,414; 9,391,143; and 10,434,749, the entire contents of each of which are incorporated by reference herein in their entirety and for all purposes. It should be appreciated that in various embodiments, the bonding layers 108a and/or 108b can comprise a non-conductive material such as a dielectric material, such as silicon oxide, or an undoped semiconductor material, such as undoped silicon. Suitable dielectric bonding surface or materials for direct bonding include but are not limited to inorganic dielectrics, such as silicon oxide, silicon nitride, or silicon oxynitride, or can include carbon, such as silicon carbide, silicon oxycarbonitride, low K dielectric materials, SiCOH dielectrics, silicon carbonitride or diamond-like carbon or a material comprising a diamond surface. Such carbon-containing ceramic materials can be considered inorganic, despite the inclusion of carbon. In some embodiments, the dielectric materials do not comprise polymer materials, such as epoxy, resin or molding materials.

In some embodiments, the device portions 110a and 110b can have a significantly different coefficients of thermal expansion (CTEs) defining a heterogenous structure. The CTE difference between the device portions 110a and 110b, and particularly between bulk semiconductor, typically single crystal portions of the device portions 110a, 110b, can be greater than 5 ppm or greater than 10 ppm. For example, the CTE difference between the device portions 110a and 110b can be in a range of 5 ppm to 100 ppm, 5 ppm to 40 ppm, 10 ppm to 100 ppm, or 10 ppm to 40 ppm. In some embodiments, one of the device portions 110a and 110b can comprise optoelectronic single crystal materials, including perovskite materials, that are useful for optical piezoelectric or pyroelectric applications, and the other of the device portions 110a, 110b comprises a more conventional substrate material. For example, one of the device portions 110a, 110b comprises lithium tantalate (LiTaO3) or lithium niobate (LiNbO3), and the other one of the device portions 110a, 110b comprises silicon (Si), quartz, fused silica glass, sapphire, or a glass. In other embodiments, one of the device portions 110a and 110b comprises a III-V single semiconductor material, such as gallium arsenide (GaAs) or gallium nitride (GaN), and the other one of the device portions 110a and 110b can comprise a non-III-V semiconductor material, such as silicon (Si), or can comprise other materials with similar CTE, such as quartz, fused silica glass, sapphire, or a glass.

In various embodiments, direct hybrid bonds can be formed without an intervening adhesive. For example, nonconductive bonding surfaces 112a and 112b can be polished to a high degree of smoothness. The bonding surfaces 112a and 112b can be cleaned and exposed to a plasma and/or etchants to activate the surfaces 112a and 112b. In some embodiments, the surfaces 112a and 112b can be terminated with a species after activation or during activation (e.g., during the plasma and/or etch processes). Without being limited by theory, in some embodiments, the activation process can be performed to break chemical bonds at the bonding surfaces 112a and 112b, and the termination process can provide additional chemical species at the bonding surfaces 112a and 112b that improves the bonding energy during direct bonding. In some embodiments, the activation and termination are provided in the same step, e.g., a plasma to activate and terminate the surfaces 112a and 112b. In other embodiments, the bonding surfaces 112a and 112b can be terminated in a separate treatment to provide the additional species for direct bonding. In various embodiments, the terminating species can comprise nitrogen. For example, in some embodiments, the bonding surface(s) 112a, 112b can be exposed to a nitrogen-containing plasma. Further, in some embodiments, the bonding surfaces 112a and 112b can be exposed to fluorine. For example, there may be one or multiple fluorine peaks at or near a bond interface 118 between the first and second elements 102, 104. Thus, in the directly bonded structure 100, the bond interface 118 between two non-conductive materials (e.g., the bonding layers 108a and 108b) can comprise a very smooth interface with higher nitrogen content and/or fluorine peaks at the bond interface 118. Additional examples of activation and/or termination treatments may be found throughout U.S. Pat. Nos. 9,564,414; 9,391,143; and 10,434,749, the entire contents of each of which are incorporated by reference herein in their entirety and for all purposes.

In various embodiments, conductive features 106a of the first element 102 can also be directly bonded to corresponding conductive features 106b of the second element 104. For example, a direct hybrid bonding technique can be used to provide conductor-to-conductor direct bonds along the bond interface 118 that includes covalently direct bonded non-conductive-to-non-conductive (e.g., dielectric-to-dielectric) surfaces, prepared as described above. In various embodiments, the conductor-to-conductor (e.g., conductive feature 106a to conductive feature 106b) direct bonds and the dielectric-to-dielectric hybrid bonds can be formed using the direct bonding techniques disclosed at least in U.S. Pat. Nos. 9,716,033 and 9,852,988, the entire contents of each of which are incorporated by reference herein in their entirety and for all purposes. In direct hybrid bonding embodiments described herein, conductive features are provided within non-conductive bonding layers, and both conductive and nonconductive features are prepared for direct bonding, such as by the planarization, activation and/or termination treatments described above. Thus, the bonding surface prepared for direct bonding includes both conductive and non-conductive features.

For example, non-conductive (e.g., dielectric) bonding surfaces 112a, 112b (for example, inorganic dielectric surfaces) can be prepared and directly bonded to one another without an intervening adhesive as explained above. Conductive contact features (e.g., conductive features 106a and 106b which may be at least partially surrounded by non-conductive dielectric field regions within the bonding layers 108a, 108b) may also directly bond to one another without an intervening adhesive. In various embodiments, the conductive features 106a, 106b can comprise discrete pads or traces at least partially embedded in the non-conductive field regions. In some embodiments, the conductive contact features can comprise exposed contact surfaces of through substrate vias (e.g., through silicon vias (TSVs)). In some embodiments, the respective conductive features 106a and 106b can be recessed below exterior (e.g., upper) surfaces (non-conductive bonding surfaces 112a and 112b) of the dielectric field region or non-conductive bonding layers 108a and 108b, for example, recessed by less than 30 nm, less than 20 nm, less than 15 nm, or less than 10 nm, for example, recessed in a range of 2 nm to 20 nm, or in a range of 4 nm to 10 nm. In various embodiments, prior to direct bonding, the recesses in the opposing elements can be sized such that the total gap between opposing contact pads is less than 15 nm, or less than 10 nm. The non-conductive bonding layers 108a and 108b can be directly bonded to one another without an adhesive at room temperature in some embodiments and, subsequently, the bonded structure 100 can be annealed. Upon annealing, the conductive features 106a and 106b can expand and contact one another to form a metal-to-metal direct bond. Beneficially, the use of Direct Bond Interconnect, or DBI®, techniques commercially available from Adeia of San Jose, Calif., can enable high density of conductive features 106a and 106b to be connected across the direct bond interface 118 (e.g., small or fine pitches for regular arrays). In some embodiments, the pitch of the conductive features 106a and 106b, such as conductive traces embedded in the bonding surface of one of the bonded elements, may be less than 100 microns or less than 10 microns or even less than 2 microns. For some applications, the ratio of the pitch of the conductive features 106a and 106b to one of the dimensions (e.g., a diameter) of the bonding pad is less than is less than 20, or less than 10, or less than 5, or less than 3 and sometimes desirably less than 2. In other applications, the width of the conductive traces embedded in the bonding surface of one of the bonded elements may range between 0.3 to 20 microns, e.g., in a range of 0.3 to 3 microns. In various embodiments, the conductive features 106a and 106b and/or traces can comprise copper or copper alloys, although other metals may be suitable. For example, the conductive features disclosed herein, such as the conductive features 106a and 106b, can comprise fine-grain metal (e.g., a fine-grain copper).

Thus, in direct bonding processes, a first element 102 can be directly bonded to a second element 104 without an intervening adhesive. In some arrangements, the first element 102 can comprise a singulated element, such as a singulated integrated device die. In other arrangements, the first element 102 can comprise a carrier or substrate (e.g., a wafer) that includes a plurality (e.g., tens, hundreds, or more) of device regions that, when singulated, form a plurality of integrated device dies. Similarly, the second element 104 can comprise a singulated element, such as a singulated integrated device die. In other arrangements, the second element 104 can comprise a carrier or substrate (e.g., a wafer). The embodiments disclosed herein can accordingly apply to wafer-to-wafer (W2W), die-to-die (D2D), or die-to-wafer (D2W) bonding processes. In wafer-to-wafer (W2W) processes, two or more wafers can be directly bonded to one another (e.g., direct hybrid bonded) and singulated using a suitable singulation process. After singulation, side edges of the singulated structure (e.g., the side edges of the two bonded elements) may be substantially flush and may include markings indicative of the common singulation process for the bonded structure (e.g., saw markings if a saw singulation process is used).

As explained herein, the first and second elements 102 and 104 can be directly bonded to one another without an adhesive, which is different from a deposition process and results in a structurally different interface compared to a deposition. In one application, a width of the first element 102 in the bonded structure is similar to a width of the second element 104. In some other embodiments, a width of the first element 102 in the bonded structure 100 is different from a width of the second element 104. Similarly, the width or area of the larger element in the bonded structure may be at least 10% larger than the width or area of the smaller element. The first and second elements 102 and 104 can accordingly comprise non-deposited elements. Further, directly bonded structures 100, unlike deposited layers, can include a defect region along the bond interface 118 in which nanometer-scale voids (nanovoids) are present. The nanovoids may be formed due to activation of the bonding surfaces 112a and 112b (e.g., exposure to a plasma). As explained above, the bond interface 118 can include concentration of materials from the activation and/or last chemical treatment processes. For example, in embodiments that utilize a nitrogen plasma for activation, a nitrogen peak can be formed at the bond interface 118. The nitrogen peak can be detectable using secondary ion mass spectroscopy (SIMS) techniques. In various embodiments, for example, a nitrogen termination treatment (e.g., exposing the bonding surface to a nitrogen-containing plasma) can replace OH groups of a hydrolyzed (OH-terminated) surface with NH2 molecules, yielding a nitrogen-terminated surface. In embodiments that utilize an oxygen plasma for activation, an oxygen peak can be formed at the bond interface 118. In some embodiments, the bond interface 118 can comprise silicon oxynitride, silicon oxycarbonitride, or silicon carbonitride. As explained herein, the direct bond can comprise a covalent bond, which is stronger than van Der Waals bonds. The bonding layers 108a and 108b can also comprise polished surfaces that are planarized to a high degree of smoothness.

In various embodiments, the metal-to-metal bonds between the conductive features 106a and 106b can be joined such that metal grains grow into each other across the bond interface 118. In some embodiments, the metal is or includes copper, which can have grains mostly oriented along the 111 crystal plane for improved copper diffusion across the bond interface 118. In some embodiments, the conductive features 106a and 106b may include nanotwinned copper grain structure, which can aid in merging the conductive features during anneal. The bond interface 118 can extend substantially entirely to at least a portion of the bonded conductive features 106a and 106b, such that there is substantially no gap between the non-conductive bonding layers 108a and 108b at or near the bonded conductive features 106a and 106b. In some embodiments, a barrier layer may be provided under and/or laterally surrounding the conductive features 106a and 106b (e.g., which may include copper). In other embodiments, however, there may be no barrier layer under the conductive features 106a and 106b, for example, as described in U.S. Pat. No. 11,195,748, which is incorporated by reference herein in its entirety and for all purposes.

Beneficially, the use of the hybrid bonding techniques described herein can enable extremely fine pitch between adjacent conductive features 106a and 106b, and/or small pad sizes. For example, in various embodiments, the pitch p (i.e., the distance from edge-to-edge or center-to-center, as shown in FIG. 1A) between adjacent conductive features 106a (or 106b) can be in a range of 0.5 microns to 50 microns, in a range of 0.75 microns to 25 microns, in a range of 1 micron to 25 microns, in a range of 1 micron to 10 microns, or in a range of 1 micron to 5 microns. Further, a major lateral dimension (e.g., a pad diameter) can be small as well, e.g., in a range of 0.25 microns to 30 microns, in a range of 0.25 microns to 5 microns, or in a range of 0.5 microns to 5 microns.

As described above, the non-conductive bonding layers 108a, 108b can be directly bonded to one another without an adhesive and, subsequently, the bonded structure 100 can be annealed. Upon annealing, the conductive features 106a, 106b can expand and contact one another to form a metal-to-metal direct bond. In some embodiments, the materials of the conductive features 106a, 106b can interdiffuse during the annealing process.

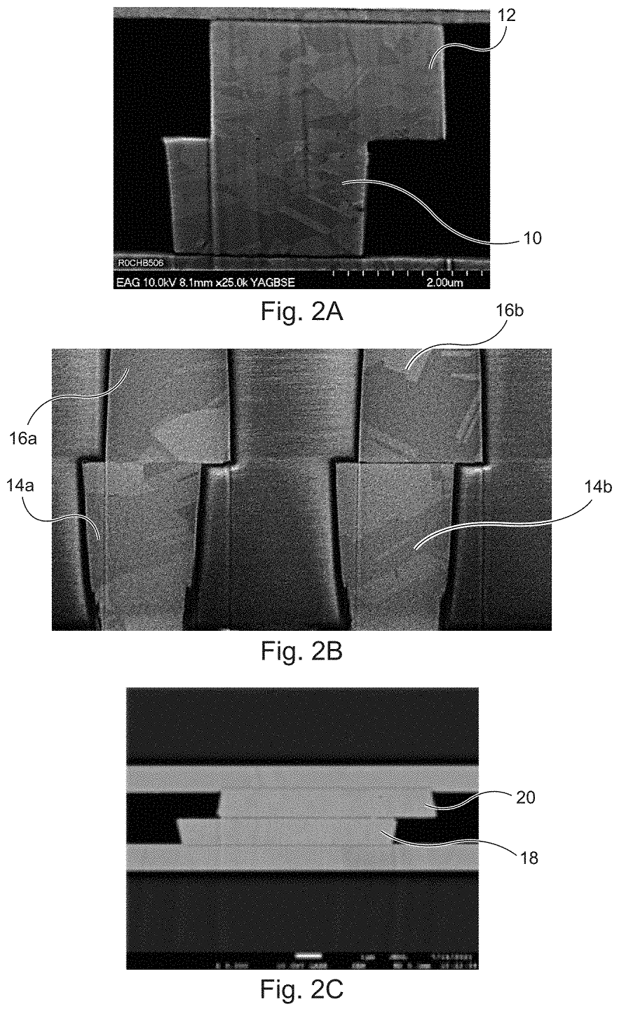

A grain size of a conductive feature can affect the bonding strength between the conductive feature and another conductive feature (e.g., the conductive features 106a, 106b). In some embodiments, the conductive feature can comprise a metal feature, such as a copper contact pad or line. A conductive feature with relatively small grains can be energetically unstable, and the grains can drive to equilibrium over time. Therefore, the conductive features with relatively small gain sizes can bond to one another with a relatively high bonding strength even with minimal application of heat, and lower anneal temperatures can be achieved for direct bonding with relatively small grain sizes. The bonding strength between such conductive features with relatively small grain sizes is greater than a bonding strength between single crystal or large grain conductive features for a given anneal temperature. In fact, a single grain across the surface of a metal feature may completely prevent bonding as shown in the right hand feature of FIG. 2B. In some embodiments, both the conductive features to be bonded can comprise relatively small grain conductive features. In some other embodiments, one of the conductive features can comprise the relatively small grain conductive feature, and the other one of the conductive features can have a larger grain conductive feature having a plurality of grain boundaries at the bonding surface. The bond between the small grain conductive features by interdiffusion can provide sufficiently reliable metal to metal bonding, while the bond between single crystal or large grain conductive features by interdiffusion for a given anneal temperature may not provide reliable conductor to conductor (e.g., metal to metal) bonding. Impurities at grain boundaries can inhibit or impede the grains to move and to bond. Therefore, minimal impurities may be preferred near the bond interface. For example, in various embodiments disclosed herein, grain boundaries of a conductive material at or near the bond interface can have less than 20 parts per million (ppm) of impurities, such as 1 ppm or 3 ppm of impurities. In some embodiments, grain boundaries of a conductive material at or near the bond interface can have 1 ppm to 20 ppm, 5 ppm to 20 ppm, 1 ppm to 15 ppm, or 5 ppm to 15 ppm of impurities. The impurities can be measured using, for example, a secondary ion mass spectrometry (SIMS) scanning technique. For example, concentrations of various elements can be mapped relative to grain structure, including boundaries, using a time of flight SIMS (TOF-SIMS). Crystal orientations of the conductive material can be determined using, for example, an electron backscatter diffraction (EBSD) technique. A grain boundary construction of the conductive material can be determined using, for example, an electron microscopy (EM) technique, such as a high-resolution transmission electron microscopy (HRTEM) technique. A number of sites with a certain impurity can be estimated based on the determined construction of the conductive material.

In general, the grain sizes near the bond interface can be observed on a surface of the conductive feature (before bonding) or in a cross-sectional view of the conductive feature. As one goal is to allow grain boundaries of the conductive features on opposing elements to intersect one another and facilitate mobility and thus direct bonding, a grain size may be measured relative to the lateral size of the conductive feature to be bonded. In conventionally processed substrates, as pitches and conductive feature (e.g., bonding pads, vias, traces, or TSVs) lateral dimensions shrink in successive generations of integrated circuits (ICs), the grain sizes as a percentage of the feature grows (e.g., as in bamboo grain structures) and it becomes less likely that grain boundaries cross one another when hybrid direct bonding. Small grains, compared to conventional processing and/or compared to the lateral dimensions of the conductive feature made up of multiple grains or sub-grains at a direct bond interface, can be advantageous for mobility to facilitate direct bonding the conductive features. Presenting multiple grains at the bond interface increases the odds or probability of grain boundaries from opposite elements intersecting, even for the relatively small conductive feature sizes employed in today's ICs and in the future which are expected to be smaller. Therefore, having small grains at the bond interface enables a greater number of grain boundarie present at the bond interface and increases the odds or probability of forming a bond as compared to having a larger grain(s) at the bond interface that provides less grain boundaries (e.g., a single grain) at the bond interface. The conductive features, such as bonding pads, vias (e.g., TSVs), traces, or through substrate electrodes of embodiments described herein can have maximum lateral dimension in a range between about 0.01 μm and 15 μm, between about 0.1 μm and 10 μm, between about 0.5 μm and 8 μm, between about 2 μm and 5 μm, between about 1 μm and 3 μm, or between about 0.01 μm and 1 μm. An example of a relatively small, high pitch bond pad, for example, can have an entire exposed area of the conductive feature at the bonding interface that is smaller than about 7 μm².

Grain sizes at the upper surface of a conductive feature that will form part of a hybrid direct bond interface prior to bonding will be described. Thus, grain sizes at the upper surface of a conductive feature that will form part of a hybrid direct bond interface can be less than 20%, less than 10%, less than 5%, or less than 2% of a contact surface of the conductive feature that is configured to contact a corresponding contact surface of another element prior to bonding. The percentages can be calculated by dividing average or maximum grain sizes and by the conductive feature size, where both grain and feature sizes are measured linearly in a lateral (e.g., x or y) dimension (linear lateral dimension), for example in a vertical cross section. In terms of area, interface grain (as measured laterally at the bond interface) can be less than 2000 nm², less than 1000 nm², less than 500 nm², less than 300 nm², or less than 180 nm² prior to bonding. Such relatively small grains can result in a conductive feature that has between 3 to 20 grains, 3 to 15 grains, or 4 to 8 grains exposed at the bonding surface, which maximizes chances of intersecting grain boundaries at the bond interface between two directly bonded conductive features. Maximum lateral dimensions for the grains at the bond interface can be less than 200 nm, less than 100 nm, less than 50 nm, less than 25 nm, less than 20 nm, or less than 15 nm prior to bonding.

Grain sizes at the upper surface of the conductive feature that forms part of the hybrid direct bond interface after bonding will be described. The interface grain size can be less than 30%, less than 20%, or less than 15% of a contact surface of the conductive feature after bonding, which can include an anneal to expand the conductive features into contact, which tends to grow the grain sizes relative to pre-bonding sizes, but remain small compared to post-anneal grains produced by conventional high volume manufacturing, as described below. As with the pre-bonding comparisons, these percentages can be calculated by dividing average or maximum grain sizes and dividing them by the conductive feature size, where both grain and feature sizes are measured linearly in a lateral (e.g., x or y) dimension, for example in a vertical cross section. An interface grain size (as measured laterally in a vertical cross-sectional view) can mean, for example, that a size of a grain is less than 71000 nm², less than 50000 nm², less than 20000 nm², less than 10000 nm², or less than 8000 nm² after bonding.

Grain sizes of conductive features manufactured using a conventional high volume manufacturing process (e.g., a bottom up plating) can be relatively large. It can be advantageous to have such large grain sizes in the bulk of conductive features, as such grains are more stable than smaller grains and can demonstrate better conductivity and signal speed and less electro-migration. However, as noted above, such large grains can be a disadvantage at a direct bond interface. One way to achieve smaller grain boundaries is to employ impurities that suppress grain growth during a plating process. However, such processes incorporate high concentrations of impurities, particularly at grain boundaries, which can present separate impediments to conductive material mobility at a bond interface. It can be challenging to form conductive features with relatively small grain sizes without impurities using such conventional processes. Also, it can be time consuming and economically inefficient to form a relatively big conductive feature that includes only small grains, and can have an adverse effect on stability and conductivity. Further, forming a relatively big conductive feature that includes only small grains can form unwanted voids in the conductive features.

Generally speaking, impurities in a plated conductive material (e.g., copper) can include, for example, carbon, oxygen, nitrogen, sulfur. The impurities can include, for example, non-alloying impurities that do not form an alloy with the conductive material (e.g., copper) of the contact pad. In other examples, impurities can comprise silicon oxide particles or silicon carbide.

FIG. 2A is a cross sectional image of two conductive features (a first conductive feature 10 and a second conductive feature 12) that are bonded to one another. The first and second conductive features 10, 12 in the image of FIG. 2A include fine grain copper (Cu) with multiple overlapping grain boundaries at the bond interface. The fine grain metal can be defined as a metal having an average grain width less than 15 nm, less than 20 nm, less than 50 nm, less than 100 nm, less than 200 nm, less than 300 nm, or less than 500 nm. For example, the maximum width of grains in the fine grain metal can be in a range of 10 nm to 500 nm, 10 nm to 300 nm, 15 nm to 500 nm, 15 nm to 300 nm, 15 nm to 100 nm, 15 nm to 50 nm, 50 nm to 500 nm, 50 nm to 300 nm, or 100 nm to 300 nm. In some embodiments, most of the grains in the fine grain metal can have a width in a range of 10 nm to 500 nm, 10 nm to 300 nm, 15 nm to 500 nm, 15 nm to 300 nm, 15 nm to 100 nm, 15 nm to 50 nm, 50 nm to 500 nm, 50 nm to 300 nm, or 100 nm to 300 nm. In an example process, the fine grain copper was plated at a plating rate on the order of 0.28 μm per minute. FIG. 2A shows that a great number of grains of the first and second conductive features 10, 12 intersect a bonding interface between the first and second conductive features 10, 12, which can contribute to providing a reliable direct bonding between the first and second conductive features 10, 12.

FIG. 2B is a cross sectional image of conductive features 14a, 16a that are bonded to one another and conductive features 14b, 16b that are not bonded to one another. The grains in the conductive features 14a, 14b, 16a, 16b are relatively large compared to the overall feature size (e.g., there are a limited number of grain boundaries at the surface of the feature). FIG. 2B shows that the conductive features 14b, 16b were prepared to be bonded to one another. However, the conductive features 14b, 16b did not bond to one another. The structure shown in FIG. 2B can indicate that a grain of the conductive feature 14b that extends or spans nearly across the entire bond interface of the conductive feature 14b has prevented a metal-metal bond from forming. Accordingly, there is not enough grain boundary overlap between the conductive features 14b, 16b to bond. This indicates that for features where the grain size is large compared to the feature size or the bond interface of a conductive feature, the probability of metal features not bonding can be significant. Therefore, for an array of a relatively large number of bonding features, some number of them will not bond thus lowering the yield.

FIG. 2C is a cross sectional image of fine copper pads 18, 20 that include a large amount of impurities that are bonded to one another only in small point areas. As discussed herein one way to provide relatively small grains (e.g., fine grains) is to introduce impurities that suppress grain growth during a plating process. FIG. 2C shows a less reliable bonding between the fine copper pads 18, 20 than the first and second conductive features 10, 12 of FIG. 2A.

Various embodiments disclosed herein relate to methods of forming conductive features that include relatively small grains at or near a bonding surface without excessive impurities or voids. According to various embodiments, a conductive feature can be formed using two or more different processes. In one example, a plating process and vapor deposition process can be used to form the conductive feature. In another example, a first plating process at a first rate and a second plating process at a second rate (for example, using a higher current density) can be used to form the conductive feature. In still another example, a first conductor formation process provides the majority of the conductive feature, an anneal is conducted to form larger, more stable grains, and a second conductor formation process provides the surface of the conductive feature and no anneal is performed between that formation and a bonding process. Methods taught herein can form smaller grains near the bonding interface and larger grains farther away from the interface, but without excessive additives in the grain boundaries near the interface.

As relatively small grains can grow over time, it can be advantageous to bond the conductive feature (a first conductive feature) to the other conductive feature (a second conductive feature) relatively quickly. For example, bonding the first conductive feature to the second conductive feature within one to two weeks after forming the first and second conductive features can maximize chances of a successful metal-to-metal direct bond. It has been found that storing chips or wafers after production for longer periods of time (e.g., 6 months or a year) can cause large grain growth, large grain sizes tend to inhibit metal-to-metal bonding, likely due to the reduced creep rate of large grains or their fewer intersecting grain boundaries in the conductive features.

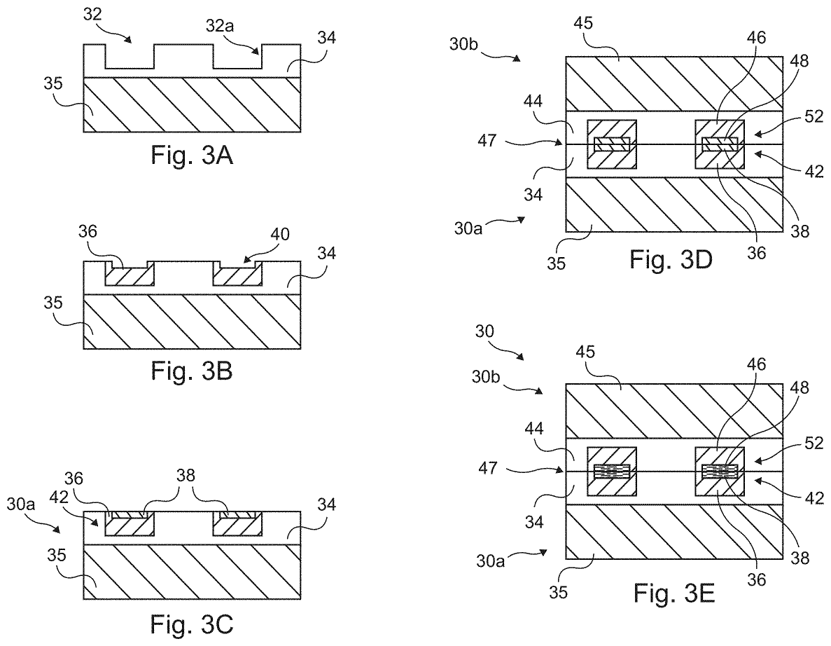

FIGS. 3A to 3E illustrate various steps of a manufacturing process of manufacturing a bonded structure 30 according to an embodiment. At FIG. 3A, a cavity 32 can be formed in a non-conductive structure 34. In some embodiments, the non-conductive structure 34 can be disposed over a device portion 35. At FIG. 3B, the cavity 32 can be at least partially filled with a first conductive material 36 using a first deposition process. The first conductive material 36 can comprise copper. In some embodiments, the first conductive material 36 can be plated into the cavity 32 by way of a bottom-up fill process using relatively low current density (e.g., less than 30 mA per cm², more particularly less than 15 mA per cm²) and relatively low rate of deposition. A side wall 32 of the cavity 32 can be fully covered by the first conductive material 36. In some embodiments, the first conductive material 36 can be annealed, prior to deposition of a second conductive material 38, to grow and stabilize grains of the first conductive material 36. The first deposition process can be halted prior to completely filling the cavity 32, as shown, thereby leaving an opening 40 in the cavity 32.

At FIG. 3C, a second conductive material 38 can be provided in the opening 40 over the first conductive material 36 in the cavity 32 using a second deposition process. The second conductive material 38 can comprise copper. In some embodiments, the second conductive material 38 can be provided by plating at a higher deposition rate (higher current density) than the first deposition process, using relatively low additive concentrations. For example, a relatively high current density, such as greater than or equal to about 2 ampere per square decimeter (ASD) or amps/dm2, can be employed to form relatively fine grains. However, very high current densities, such as higher than 7 ASD or the mass transfer limit of the plating bath, should be avoided to minimize rough or porous metal coating. In some embodiments, the first deposition process comprises plating, and the second deposition process comprises vapor deposition, such as chemical vapor deposition (CVD) or physical vapor deposition (PVD). Whether formed by a different plating process or a vapor deposition process, the grain sizes of the second conductive material 38 are on average observably smaller than the grain sizes of the first conductive material 36, and/or impurities such as those present from plating additives for grain control are observably smaller for the second conductive material 38 compared to the first conductive material 36. In some embodiments, the first conductive material 36 can include more impurities that the second conductive material 38.

A surface that comprises at least a portion of the non-conductive structure 34 and at least a portion of the second conductive material 38 can be polished and the surface can be treated (e.g., activated and terminated) to define a bonding surface of an element (e.g., a first element 30a). In some embodiments, a surface of the second conductive material 38 can be flush with or generally flush with a surface of the non-conductive structure 34. In some other embodiments, the surface of the second conductive material 38 can be recessed relative to the surface of the non-conductive structure 34, as described above. A thickness of the second conductive material 38 can be less than 70%, less than 30%, or less than 20% of a thickness of a conductive feature 42 (a combination of the first conductive material 36 and the second conductive material 38). In some embodiments, the thickness of the second conductive material 38 can be 30 nm to 600 nm, and the thickness of the first conductive material 36 can be 400 nm to 5000 nm.

At FIG. 3D, the element (the first element 30a) formed in FIG. 3C can contact another element (a second element 30b). The second element 30b can have the same or a generally similar structure as the first element 30a. Although the first conductive material 36 may be annealed prior to formation of the second conductive material 38, the second conductive material 38 may not be annealed prior to bonding, or can be annealed at lower temperatures and/or shorter durations compared to the first conductive material anneal with large grains at their bonding surface, as described above. The non-conductive structure 34 of the first element 30a and a non-conductive structure 44 of the second element 30b can be bonded to one another along a bond interface 47 upon contacting the first element 30a to the second element 30b at room temperature. In some embodiments, the non-conductive structure 44 can be disposed over a device portion 45. In some embodiments, the second conductive material 38 of the first element 30a and a conductive feature 52 (which can comprise a third conductive material 46 and a fourth conductive material 48) of the second element 30b can be bonded to one another along the bond interface 47 upon contacting the first element 30a to the second element 30b at room temperature. At FIG. 3E, the contacted first and second elements 30a, 30b can be annealed after initial room temperature bonding of the non-conductive features 42, 52; such post-bond annealing allows the conductive features to expand into one another to complete the hybrid bonding and form the bonded structure 30. In the bonded structure 30, the grain size of the second conductive material 38 may remain smaller than the grain size of the first conductive material 36 in some embodiments.

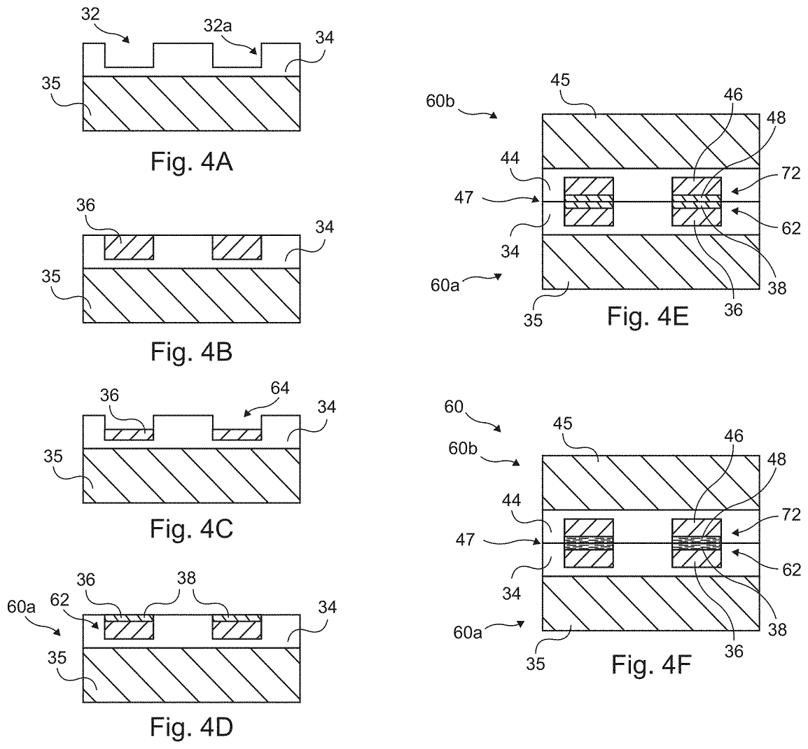

FIGS. 4A to 4F illustrate various steps of a manufacturing process of manufacturing a bonded structure 60 according to an embodiment. At FIG. 4A, a cavity 32 can be formed in a non-conductive structure 34. At FIG. 4B, the cavity 32 can be filled with a first conductive material 36 using a first deposition process. The first conductive material 36 can comprise copper. In some embodiments, the first conductive material 36 can be plated into the cavity 32 by way of a bottom-up fill process using relatively low current density (e.g., less than 2 amps per square decimeter (ASD), more particularly less than 0.5 ASD, or less than 30 mA per cm², more particularly less than 15 mA per cm²) and relatively low rate of deposition. In some embodiments, the cavity 32 can be completely filled with the first conductive material 36. Typically the cavity 32 is over-filled, and a CMP process is employed to remove the conductive material overburden from over the non-conductive material 34, and the conductive material overburden is subsequently be remove or planarized to form the structure shown in FIG. 4B. In some embodiments, the first conductive material 36 can be annealed, to grow and stabilize grains of the first conductive material 36 prior to deposition of a second conductive material 38.

At FIG. 4C, at least a portion of the first conductive material 36 can be removed to define an opening 64. In some embodiments, the first conductive material 36 can be selectively removed by way of etching (e.g., wet etching) to form a recess or the opening 64 in first conductive feature 36 shown in FIG. 2C. In some embodiments, a barrier layer (not shown) can be provided at least partially on surfaces of the cavity 32. After forming the barrier layer, the first conductive material 36 can be provided such that the barrier layer intervenes the surfaces of the cavity 32 and the first conductive material 36. In some embodiments a portion of the first conductive material 36 can be selectively removed without removing the barrier layer. A recess or the opening 64 can be formed by removing a portion of the first conductive material 36 disposed in the cavity 32 of the non-conductive material 34. The first conductive material 36 with the recess may be annealed to enlarge or stabilize the grains.

At FIG. 4D, a second conductive material 38 can be provided over the first conductive material 36 in the cavity 32 using a second deposition process. The second conductive material 38 can comprise copper. In some embodiments, the second conductive material 38 can be provided by plating at a higher deposition rate (higher current density) than the first deposition process, with using low additive concentrations. For example, a relatively high current density, such as greater than or equal to about 2 ASD, can be employed to form relatively fine grains. However, very high current densities, such as higher than 7 ASD or 10 ASD, may not be preferred as deposition with very high current densities can cause the material to be rough or porous. In some embodiments, the first deposition process comprises plating, and the second deposition process comprises vapor deposition, such as chemical vapor deposition (CVD) or physical vapor deposition (PVD). Whether formed by a different plating process or a vapor deposition process, the grain sizes of the second conductive material 38 are on average observably smaller than the grain sizes of the first conductive material 36, and impurities such as those present from plating additives for grain control are observably smaller for the second conductive material 38 compared to the first conductive material 36.

A surface that comprises at least a portion of the non-conductive structure 34 and at least a portion of second conductive material 38 can be polished and treated (e.g., activated and terminated) to define a bonding surface of an element (e.g., a first element 60A). In some embodiments, a surface of the second conductive material 38 can be flush with or generally flush with a surface of the non-conductive structure 34. In some other embodiments, the surface of the second conductive material 38 can be recessed relative to the surface of the non-conductive structure 34, as described above.

The pre-bonding recess may have a depth below the non-conductive bonding surface of less than 75 nm, less than 50 nm and preferably less than 20 nm, in some embodiments. A thickness of the second conductive material 38 can be less than 70%, less than 50%, less than 30%, or less than 20% of a thickness of a conductive feature 62 (a combination of the first conductive material 36 and the second conductive material 38). In some embodiments, the thickness of the second conductive material 38 can be 30 nm to 600 nm, and the thickness of the first conductive material 36 can be 400 nm to 5000 nm. In some embodiment, the thickness of the second conductive material 38 can be more than 50 nm.

At FIG. 2E, the element (the first element 60a) formed in FIG. 2D can contact another element (a second element 60b). Although the first conductive material 36 may be annealed prior to formation of the second conductive material 38, the second conductive material 38 may not be annealed prior to bonding, or can be annealed at lower temperatures and/or lower durations compared to the first conductive material anneal, such that the grains for the second conductive material 38 remain small as described above. The second element 60b can have the same or generally similar structure as the first element 60a. The non-conductive structure 34 of the first element 60a and a non-conductive structure 44 of the second element 60b can be bonded to one another along a bond interface 47 upon contacting the first element 60a to the second element 60b at room temperature. In some embodiments, the second conductive material 38 of the first element 60a and a conductive feature 72 (which can comprise a third conductive material 46 and a fourth conductive material 48) of the second element 60b can be bonded to one another along the bond interface 47 upon contacting the first element 60a to the second element 60b at room temperature. At FIG. 2F, the contacted first and second elements 60a, 60b can be annealed after initial room temperature bonding of the non-conductive features 34, 44; such post-bond annealing allows the conductive features 62, 72 to expand into one another to complete the hybrid bonding and to form the bonded structure 60. In the bonded structure 60, the grain size of the second conductive material 38 can remain smaller on average than the grain size of the first conductive material 36.

Components of FIGS. 3A-3E and 4A-4F can be the same as or generally similar to like components disclosed herein, for example, those of FIGS. 1A and 1B. For example, the non-conductive features 42, 52 can be the same as or generally similar to the non-conductive bonding layers 108a, 108b; and the device portions 35, 45 can be the same as or generally similar to the device portions 110a, 110b.

Both in the embodiment shown in FIGS. 3A to 3E and the embodiments shown in FIGS. 4A to 4F, the second conductive material 38 can comprise small or fine grains. A maximum grain size of the second conductive material 38 (as measured in a lateral dimension in a vertical cross section) can be less than 20%, less than 10%, less than 5%, or less than 2% of a maximum lateral dimension of a contact surface of the conductive feature 62 prior to bonding. In terms of area occupied at the bonding interface, the grains can be less than 2000 nm², less than 1000 nm², less than 500 nm², less than 300 nm², or less than 180 nm²prior to bonding. A maximum grain size of the second conductive material 38, as measured linearly in a lateral dimension, can be less than 500 nm, less than 200 nm, less than 100 nm, less than 50 nm, less than 25 nm, less than 20 nm, or less than 15 nm, prior to bonding. For example, the maximum width of grain in the second conductive material 38 can be in a range of 10 nm to 500 nm, 10 nm to 300 nm, 15 nm to 500 nm, 15 nm to 300 nm, 15 nm to 100 nm, 15 nm to 50 nm, 50 nm to 500 nm, 50 nm to 300 nm, or 100 nm to 300 nm.

By way of contrast, the lower first conductive material 36 can have larger grains. For example, in terms of lateral area, grains of the first conductive material can be greater than 2000 nm², greater than 4000 nm², greater than 7000 nm², or greater than 10000 nm² prior to bonding. A maximum grain size of the first conductive material, as measured linearly in a lateral dimension, can be greater than 50 nm, greater than 100 nm, greater than 300 nm, or greater than 500 nm, prior to bonding. Prior to bonding, an average size of the first conductive material is greater than an average size of the second conductive material. In some embodiments, the average size of the first conductive material can be 10% to 200% greater than the average size of the second conductive material both prior to bonding, and after bonding.

As noted above, annealing after initial bonding allows the conductive features 42, 52, 62, 72 of opposite elements 30a, 30b, 60a, 60b to further grow into one another and complete the hybrid bonding. This annealing will also grow the grain sizes of the second conductive material 38, but the second conductive material average grain size of the second conductive material 38 will remain smaller than the average conductive material grain size of the underlying first conductive material 36. Although both first and second conductive materials 36, 38 may largely comprise the same metal or metal alloy (e.g., copper), they can be distinguished both by observably different average and maximum grain sizes and in some embodiments by notably higher additive impurities in the first conductive material 36 compared to the second conductive material 38. A maximum lateral dimension of grain size of the second conductive material 38 can be less than 200 nm, less than 150 nm, less than 100 nm, less than 50 nm, or less than 20 nm, prior to bonding. A maximum lateral cross-sectional area of the second conductive material 38 can be less than 2000 nm², less than 1000 nm², less than 500 nm², less than 300 nm², or less than 180 nm² prior to bonding. Due to grain growth during anneal, a maximum lateral dimension of grain size of the second conductive material 38 can be less than 2 μm, less than 1 μm, less than 500 nm, or less than 300 nm, after bonding. A maximum lateral cross-sectional area of the second conductive material 38 can be less than 4 μm², less than 1 μm², less than 250,000 nm², after bonding.

Although the grains grow during anneal, the grains of the second conductive materials 38 remains relatively small in relation to the conductive feature 42, 62. A maximum grain size of the second conductive material 38, as measured linearly in a lateral dimension, can be less than 30%, less than 20%, or less than 15% of a width of the conductive feature 42, 62 after bonding, where both the grain and feature sizes are measured linearly in a lateral dimension. The smaller grains of the second conductive material 38 may represent the top 1-20 layers of grains, more particularly the top 2-5 grain layers, from the bond interface 47 whereas grains farther from the bond interface 47 are larger and may include higher impurity concentrations. After bonding, depending at least in part on the temperature profile of the post bonding high temperature anneal, for example for a temperature of 200° C. or lower, and for a bonding time of 60 minutes, an average size of the first conductive material 36 can remain greater than an average size of the second conductive material 38. In some embodiments, the average size of the first conductive material 36 can be 2 to 4 times greater than the average size of the second conducive material 38, after bonding.

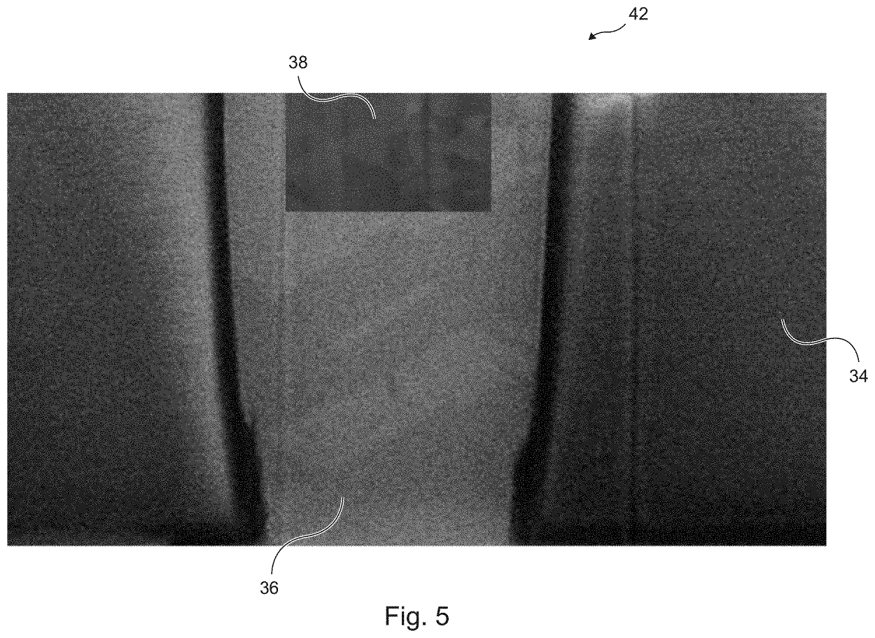

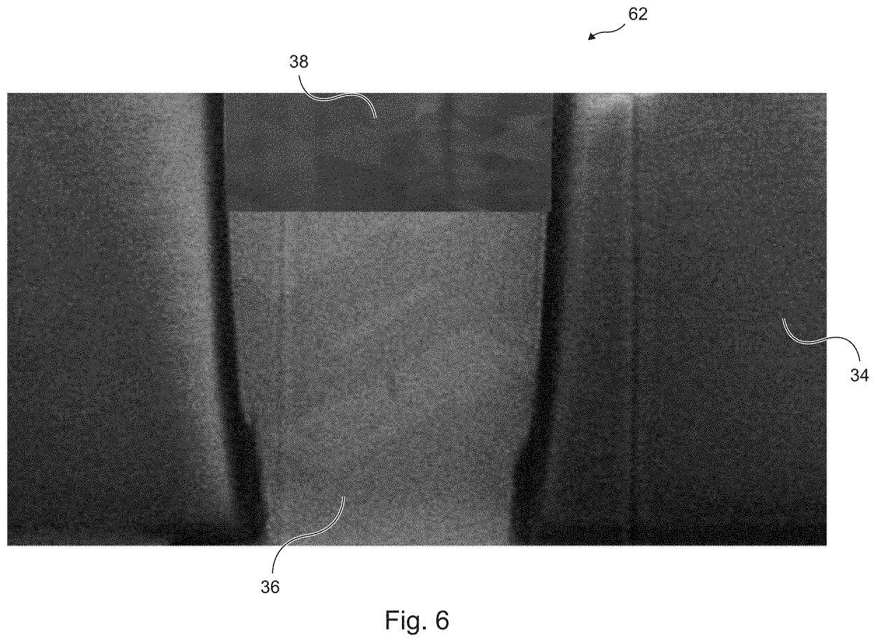

FIG. 5 is an image generated to show how a conductive feature 42 that includes a first conductive material 36 and a second conductive material 38 would appear. FIG. 6 is an image generated to show how a conductive feature 62 that includes a first conductive material 36 and a second conductive material 38 would appear. FIGS. 5 and 6 show that the grain sizes of the first and second conductive materials 36, 38 are visibly different. A skilled artisan will know that the conductive features 42, 62 each comprise a portion that includes larger grains (e.g., the first conductive material 36) and a visibly distinctive portion that includes smaller grains (e.g., the second conductive material 38).

In one aspect, a method for forming an element is disclosed. The method can include providing a non-conductive structure and forming a cavity in the non-conductive structure. The cavity at least partially extends through a thickness of the non-conductive structure from a surface of the non-conductive structure. The method can include providing a conductive feature that includes a first conductive material and a second conductive material over the first conductive material in the cavity. The second conductive material is positioned at a bonding surface of the element. A maximum grain size of the second conductive material, in a linear lateral dimension, is smaller than 20% of the linear lateral dimension of the conductive feature. The method can include preparing the bonding surface of the element for direct bonding.

In one embodiment, there are less than 20 parts per million (ppm) of impurities at grain boundaries of the second conductive material.

In one embodiment, an average grain size of the second conductive material is smaller than an average grain size of the first conductive material.

In one embodiment, the providing the conductive feature comprises separately providing the first conductive material and the second conductive material. The providing the first conductive material can include partially filling the cavity. The providing the first conductive material can include filling the cavity with the first conductive material and removing a portion of the first conductive material. The method can further include annealing the first conductive material prior to providing the second conductive material. The providing the conductive material can include providing the second conductive material over the first conductive material by way of plasma vapor deposition (PVD). The second conductive material can be provided by plating at a higher current density than a first deposition process for providing the first conductive material. The preparing the bonding surface can include polishing surfaces of the non-conductive material and the second conductive material.

In one embodiment, the maximum grain size of the second conductive material is smaller than 10% of the linear lateral dimension of the conductive feature. The maximum grain size of the second conductive material can be smaller than 5% of the linear lateral dimension of the conductive feature. The maximum grain size of the second conductive material can be smaller than 2% of the linear lateral dimension of the conductive feature.

In one embodiment, an area of the conductive feature at the bonding surface is smaller than 7 μm².

In one embodiment, a maximum grain lateral area of the second conductive material at the bonding surface in a cross sectional view is smaller than 2000 nm².

In one embodiment, a maximum linear lateral grain size of the second conductive material at the bonding surface is smaller than 200 nm.

In one embodiment, the first conductive material and the second conductive material comprise copper.

In one embodiment, the method further includes providing an intervening layer between the first conductive material and the second conductive material.

In one embodiment, a thickness of the second conductive material is less than 50% of a thickness of the conductive feature. A thickness of the second conductive material can be less than 30% of a thickness of the conductive feature.

In one aspect, a method for forming a bonded structure is disclosed. The method can include providing a first element that include a first non-conductive structure that has a non-conductive bonding surface, a cavity that extends at least partially through a thickness of the non-conductive structure from the non-conductive bonding surface, and a first conductive feature that has a first conductive material and a second conductive material over the first conductive material disposed in the cavity. The second conductive material is at least partially exposed at a bonding surface of the element. An average grain size of the second conductive material is smaller than an average grain size of the first conductive material. The method can include providing a second element that includes a second non-conductive structure, and a second conductive feature. The method can include contacting the bonding surface of the first element and a bonding surface of the second element without subjecting the second conductive material to an annealing process, and directly bonding the first element and the second element after the contacting.

In one embodiment, there are less than 20 parts per million (ppm) of impurities at grain boundaries of the second conductive material

In one embodiment, the directly bonding the first element and the second element includes directly bonding the first non-conductive structure and the second non-conductive structure without an intervening adhesive, and directly bonding the first conductive feature and the second conductive feature without an intervening adhesive.

In one embodiment, the providing the first element includes providing the first non-conductive structure, forming the cavity in the first non-conductive structure, providing a first conductive material, and providing a second conductive material after providing the first conductive material. The method can further include annealing the first conductive material prior to providing the second conductive material.

In one embodiment, the method further includes annealing the bonded first and second elements.

In one embodiment, the method further includes preparing the bonding surface of the element for direct bonding. The preparing the bonding surface can include polishing surfaces of the non-conductive material and the second conductive material.

In one embodiment, a maximum grain size of the second conductive material, in a linear lateral dimension, before directly bonding the first element and the second element is smaller than 20% of the linear lateral dimension of the conductive feature. The maximum grain size of the second conductive material before directly bonding the first element and the second element can be smaller than 10% of the linear lateral dimension of the conductive feature. The maximum grain size of the second conductive material before directly bonding the first element and the second element can be smaller than 5% of the linear lateral dimension of the conductive feature.

In one embodiment, the entire exposed area of the conductive feature is smaller than 7 μm².

In one embodiment, a maximum grain lateral area of the second conductive material before directly bonding the first element and the second element is smaller than 2000 nm².

In one embodiment, a maximum linear lateral grain size of the second conductive material before directly bonding the first element and the second element is smaller than 200 nm.

In one embodiment, a maximum grain size of the second conductive material, in a linear lateral dimension, after directly bonding the first element and the second element is smaller than 30% of the linear lateral dimension of the conductive feature. The maximum grain size of the second conductive material after directly bonding the first element and the second element can be smaller than 20% of the linear lateral dimension of the conductive feature. The maximum grain size of the second conductive material after directly bonding the first element and the second element can be smaller than 15% of the linear lateral dimension of the conductive feature.

In one embodiment, a maximum grain lateral area of the second conductive material at the bonding surface after directly bonding the first element and the second element is smaller than 71000 nm².

In one embodiment, a maximum linear lateral grain size of the second conductive material at the bonding surface after directly bonding the first element and the second element is smaller than 2 μm.

In one embodiment, the first conductive material and the second conductive material include copper.

In one embodiment, the method further includes providing an intervening layer between the first conductive material and the second conductive material.

In one aspect, an element is disclosed. the element can include a non-conductive structure and a cavity in the non-conductive structure. The cavity at least partially extends through a thickness of the non-conductive structure from a surface of the non-conductive structure. The element can include a conductive feature that includes a first conductive material and a second conductive material over the first conductive material in the cavity. The second conductive material is positioned at a bonding surface of the element. A maximum grain size, in a linear lateral dimension, of the second conductive material is smaller than 20% of the linear lateral dimension of the conductive feature.

In one embodiment, there are less than 20 parts per million (ppm) of impurities at grain boundaries of the second conductive material.

In one embodiment, an average grain size, in the linear lateral dimension, of the second conductive material is smaller than an average grain size, in the linear lateral dimension, of the first conductive material

In one embodiment, a thickness of the second conductive material is less than 50% of a thickness of the conductive feature. A thickness of the second conductive material can be less than 30% of a thickness of the conductive feature.

In one embodiment, the bonding surface of the element is prepared for direct bonding. The bonding surface can have a root-mean-square (rms) surface roughness of less than 2 nm.

In one embodiment, the maximum grain size of the second conductive material is smaller than 10% of the linear lateral dimension of the conductive feature. The maximum grain size of the second conductive material can be smaller than 5% of the linear lateral dimension the conductive feature. The maximum grain size of the second conductive material can be smaller than 2% of the linear lateral dimension of the conductive feature.

In one embodiment, the linear lateral dimension of the conductive feature at the bonding surface is smaller than 7 μm².

In one embodiment, a maximum grain lateral area of the second conductive material at the bonding surface is smaller than 2000 nm².

In one embodiment, the maximum grain size of the second conductive material at the bonding surface is smaller than 200 nm.

In one embodiment, the first conductive material and the second conductive material include copper.

In one embodiment, the element further include an intervening layer between the first conductive material and the second conductive material.

In one aspect, a bonded structure is disclosed. The bonded structure can include a first element that includes a first non-conductive structure that has a non-conductive bonding surface, a cavity that extends at least partially through a thickness of the non-conductive structure from the non-conductive bonding surface, and a first conductive feature that has a first conductive material and a second conductive material over the first conductive material disposed in the cavity. An average grain size of the second conductive material is smaller than an average grain size of the first conductive material. There are less than 20 parts per million (ppm) of impurities at grain boundaries of the second conductive material. The bonded structure can include a second element that includes a second non-conductive structure, and a second conductive feature. The first element and the second element are bonded to one another such the first non-conductive structure and the second non-conductive structure are directly bonded to one another without an intervening adhesive. The second conductive material and the second conductive feature are directly bonded to one another without an intervening adhesive.

In one embodiment, a thickness of the second conductive material is less than 50% of a thickness of the conductive feature. A thickness of the second conductive material is less than 30% of a thickness of the conductive feature.

In one embodiment, the first conductive material and the second conductive material comprise copper.

In one embodiment, the bonded structure further includes an intervening layer between the first conductive material and the second conductive material.

In one embodiment, a maximum grain size of the second conductive material, in a linear lateral dimension, after directly bonding the first element and the second element is smaller than 30% of the linear lateral dimension of the conductive feature. The maximum grain size of the second conductive material after directly bonding the first element and the second element can be smaller than 20% of the linear lateral dimension of the conductive feature. The maximum grain size of the second conductive material after directly bonding the first element and the second element can be smaller than 15% of the linear lateral dimension of the conductive feature.

In one embodiment, a maximum grain lateral area of the second conductive material at a bonding surface after directly bonding the first element and the second element is smaller than 71000 nm².

In one embodiment, a maximum linear lateral grain size of the second conductive material after directly bonding the first element and the second element is smaller than 2 μm.

In one aspect, a method for forming an element is disclosed. The method can include providing a non-conductive structure, forming a cavity in the non-conductive structure, and providing a conductive feature that includes a first conductive material and a second conductive material over the first conductive material in the cavity such that the second conductive material is at least partially exposed at a bonding surface of the element. There are less than 20 parts per million (ppm) of impurities at grain boundaries of the second conductive material, and a maximum grain size of the second conductive material, in a linear lateral dimension, is smaller than 20% of the linear lateral dimension of the conductive feature.

In one embodiment, the providing the conductive feature comprises separately providing the first conductive material and the second conductive material. The providing the first conductive material can include partially filling the cavity. The providing the first conductive material can include filling the cavity with the first conductive material and removing a portion of the first conductive material. The method can further include annealing the first conductive material prior to providing the second conductive material. The providing the conductive material can include providing the second conductive material over the first conductive material by way of vapor deposition. The vapor deposition can be physical vapor deposition or chemical vapor deposition. The second conductive material can be provided by plating at a higher current density than a first deposition process for providing the first conductive material.

In one embodiment, the method further includes preparing the bonding surface of the element for direct bonding. The preparing the bonding surface can include polishing surfaces of the non-conductive material and the second conductive material. The maximum grain size of the second conductive material can be smaller than 5% of the linear lateral dimension of the conductive feature. The maximum grain size of the second conductive material can be smaller than 2% of the linear lateral dimension of the conductive feature.

In one embodiment, the entire exposed area of the conductive feature is smaller than 7 μm².

In one embodiment, a maximum grain lateral area of the second conductive material at the bonding surface is smaller than 2000 nm².

In one embodiment, the maximum grain size of the second conductive material is smaller than 200 nm.

In one embodiment, the first conductive material and the second conductive material comprise copper.

In one embodiment, the method further includes providing an intervening layer between the first conductive material and the second conductive material.

In one embodiment, a thickness of the second conductive material is less than 50% of a thickness of the conductive feature. A thickness of the second conductive material is less than 30% of a thickness of the conductive feature.

In one aspect, a method for forming a bonded structure is disclosed. The method can include providing a first element that includes a first non-conductive structure that has a non-conductive bonding surface, a cavity in the non-conductive structure, and a first conductive feature that has a first conductive material and a second conductive material over the first conductive material disposed in the cavity. The second conductive material is at least partially exposed at a bonding surface of the element. There are less than 20 parts per million (ppm) of impurities at grain boundaries of the second conductive material. A maximum grain size of the second conductive material, in a linear lateral dimension, is smaller than 20% of the linear lateral dimension of the conductive feature. The method can include providing a second element that includes a second non-conductive structure, and a second conductive feature. The method can include contacting the bonding surface of the first element and a bonding surface of the second element without subjecting the second conductive material to an annealing process, and directly bonding the first element and the second element after the contacting.

In one embodiment, the directly bonding the first element and the second element includes directly bonding the first non-conductive structure and the second non-conductive structure without an intervening adhesive, and directly bonding the first conductive feature and the second conductive feature without an intervening adhesive.

In one embodiment, the providing the first element includes providing the first non-conductive structure, forming the cavity in the first non-conductive structure, providing a first conductive material, and providing a second conductive material after providing the first conductive material. The method can further include annealing the first conductive material prior to providing the second conductive material.

In one embodiment, the method further includes annealing the bonded first and second elements.

In one embodiment, the method further includes preparing the bonding surface of the element for direct bonding. The preparing the bonding surface can include polishing surfaces of the non-conductive material and the second conductive material.

In one embodiment, the maximum grain size of the second conductive material before directly bonding the first element and the second element is smaller than 5% of the linear lateral dimension of the conductive feature. The maximum grain size of the second conductive material before directly bonding the first element and the second element can be smaller than 2% of the linear lateral dimension of the conductive feature.

In one embodiment, the entire exposed area of the conductive feature is smaller than 7 μm².

In one embodiment, a maximum grain lateral area of the second conductive material at the bonding surface before directly bonding the first element and the second element is smaller than 2000 nm².

In one embodiment, the maximum grain size of the second conductive material before directly bonding the first element and the second element is smaller than 200 nm.

In one embodiment, the maximum grain size of the second conductive material after directly bonding the first element and the second element is smaller than 30% of the linear lateral dimension linear lateral dimension of the conductive feature. The maximum grain size of the second conductive material after directly bonding the first element and the second element can be smaller than 20% of the linear lateral dimension of the conductive feature. The maximum grain size of the second conductive material after directly bonding the first element and the second element can be smaller than 15% of the linear lateral dimension of the conductive feature.

In one embodiment, a maximum grain lateral area of the second conductive material at the bonding surface after directly bonding the first element and the second element is smaller than 71000 nm².

In one embodiment, the maximum grain size of the second conductive material after directly bonding the first element and the second element is smaller than 2 μm.

In one embodiment, the first conductive material and the second conductive material comprise copper.

In one embodiment, the method further includes providing an intervening layer between the first conductive material and the second conductive material.

In one aspect, an element is disclosed. The element can include a non-conductive structure and a cavity in the non-conductive structure. The cavity at least partially extends through a thickness of the non-conductive structure from a surface of the non-conductive structure. The element can include a conductive feature that includes a first conductive material and a second conductive material over the first conductive material in the cavity. The second conductive material is positioned at a bonding surface of the element. A maximum grain size, in a linear lateral dimension, of the second conductive material is smaller than 20% of the linear lateral dimension of the conductive feature. There are less than 20 parts per million (ppm) of impurities at grain boundaries of the second conductive material.

In one embodiment, a thickness of the second conductive material is less than 50% of a thickness of the conductive feature. A thickness of the second conductive material can be less than 30% of a thickness of the conductive feature.

In one embodiment, the bonding surface of the element is prepared for direct bonding. The bonding surface can have a root-mean-square (rms) surface roughness of less than 2 nm.

In one embodiment, the maximum grain size of the second conductive material is smaller than 5% of the linear lateral dimension of the conductive feature. The maximum grain size of the second conductive material can be smaller than 2% of the linear lateral dimension of the conductive feature.

In one embodiment, the area of the conductive feature at the bonding surface is smaller than 7 μm².

In one embodiment, a maximum grain lateral area of the second conductive material at the bonding surface is smaller than 2000 nm².

In one embodiment, the maximum grain size of the second conductive material is smaller than 200 nm.

In one embodiment, the first conductive material and the second conductive material include copper.

In one embodiment, the element further includes an intervening layer between the first conductive material and the second conductive material.

In one aspect, a bonded structure is disclosed. The bonded structure can include a first element that includes a first non-conductive structure that has a non-conductive bonding surface, a cavity that extends at least partially through a thickness of the non-conductive structure from the non-conductive bonding surface, and a first conductive feature that has a first conductive material and a second conductive material over the first conductive material disposed in the cavity. The bonded structure can include a second element that includes a second non-conductive structure, and a second conductive feature. The first element and the second element are bonded to one another such the first non-conductive structure and the second non-conductive structure are directly bonded to one another without an intervening adhesive, and that the second conductive material and the second conductive feature are directly bonded to one another without an intervening adhesive. A maximum grain size of the second conductive material, in a linear lateral dimension, after directly bonding the first element and the second element is smaller than 30% of the linear lateral dimension of the conductive feature.

In one embodiment, there are less than 20 parts per million (ppm) of impurities at grain boundaries of the second conductive material.

In one embodiment, a thickness of the second conductive material is less than 50% of a thickness of the conductive feature. A thickness of the second conductive material is less than 30% of a thickness of the conductive feature.

In one embodiment, the first conductive material and the second conductive material comprise copper.

In one embodiment, the bonded structure further includes an intervening layer between the first conductive material and the second conductive material.

In one embodiment, the maximum grain size of the second conductive material after directly bonding the first element and the second element is smaller than 20% of the linear lateral dimension of the conductive feature. The maximum grain size of the second conductive material after directly bonding the first element and the second element can be smaller than 15% of the linear lateral dimension of the conductive feature.

In one embodiment, a maximum grain lateral area of the second conductive material at the bonding surface after directly bonding the first element and the second element is smaller than 71000 nm².

In one embodiment, the maximum grain size of the second conductive material after directly bonding the first element and the second element is smaller than 2 μm.

In one embodiment, the entire exposed area of the conductive feature is smaller than 7 μm².

In one aspect, a method of forming a conductive feature in a substrate for direct hybrid bonding is disclosed. The method can include depositing a first conductive material by a first deposition process that includes plating under conditions for forming a first average grain size. The method can include depositing a second conductive material by a second deposition process different from the first deposition process without increasing impurity levels relative to the first deposition process. The second deposition process forms a second average grain size smaller than the first deposition process. The method can include preparing a bonding surface that includes the second conductive material and a nonconductive surface for direct hybrid bonding.

In one embodiment, an impurity level of the first conductive material is equal to or greater than the second conductive material.

In one embodiment, the second deposition process is a process that suppresses grain growth without introducing less than 20 parts per million (ppm) of impurities at grain boundaries of the second conductive material.

In one embodiment, the first deposition process includes a plating process and the second deposition process comprises a vapor deposition process. The plating process can use current density more than 2 amp/dm².

In one embodiment, the first deposition process includes plating using a first current density and the second deposition process comprises plating using a second current density higher than the first current density.

In one embodiment, the first deposition process includes plating and the second deposition process includes vapor deposition.

In one embodiment, the first conductive material and the second conductive material include primarily copper.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Moreover, as used herein, when a first element is described as being “on” or “over” a second element, the first element may be directly on or over the second element, such that the first and second elements directly contact, or the first element may be indirectly on or over the second element such that one or more elements intervene between the first and second elements. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

What is claimed is:

1. A method for forming an element, the method comprising:
providing a non-conductive structure;
forming a cavity in the non-conductive structure, the cavity at least partially extends through a thickness of the non-conductive structure from a surface of the non-conductive structure;
providing a conductive feature including a first conductive material and a second conductive material over the first conductive material in the cavity, the second conductive material positioned at a bonding surface of the element, wherein a maximum grain size of the second conductive material, in a linear lateral dimension, is smaller than 20% of the linear lateral dimension of the conductive feature; and
preparing the bonding surface of the element for direct bonding.

2. The method of claim 1, wherein there are less than 20 parts per million (ppm) of impurities at grain boundaries of the second conductive material.

3. The method of claim 1, wherein an average grain size of the second conductive material is smaller than an average grain size of the first conductive material.

4. The method of claim 1, wherein the providing the conductive feature comprises separately providing the first conductive material and the second conductive material, and the method further comprising annealing the first conductive material prior to providing the second conductive material.

5. The method of claim 4, wherein the providing the conductive material comprises providing the second conductive material over the first conductive material by way of plasma vapor deposition (PVD), or plating at a higher current density than a first deposition process for providing the first conductive material.

6. The method of claim 1, wherein the maximum grain size of the second conductive material is smaller than 10% of the linear lateral dimension of the conductive feature.

7. The method of claim 1, wherein a maximum linear lateral grain size of the second conductive material at the bonding surface is smaller than 200 nm.

8. The method of claim 1, wherein a thickness of the second conductive material is less than 50% of a thickness of the conductive feature.

9. A method for forming a bonded structure, the method comprising:
providing a first element including:
a first non-conductive structure having a non-conductive bonding surface,
a cavity extending at least partially through a thickness of the non-conductive structure from the non-conductive bonding surface, and
a first conductive feature having a first conductive material and a second conductive material over the first conductive material disposed in the cavity, the second conductive material at least partially exposed at a bonding surface of the element, wherein an average grain size of the second conductive material is smaller than an average grain size of the first conductive material;
providing a second element including:
a second non-conductive structure, and
a second conductive feature; and
contacting the bonding surface of the first element and a bonding surface of the second element without subjecting the second conductive material to an annealing process; and
directly bonding the first element and the second element after the contacting.

10. The method of claim 9, wherein there are less than 20 parts per million (ppm) of impurities at grain boundaries of the second conductive material.

11. The method of claim 9, wherein the directly bonding the first element and the second element comprises directly bonding the first non-conductive structure and the second non-conductive structure without an intervening adhesive, and directly bonding the first conductive feature and the second conductive feature without an intervening adhesive.

12. The method of claim 9, wherein the providing the first element comprises:
providing the first non-conductive structure;
forming the cavity in the first non-conductive structure;
providing a first conductive material;
providing a second conductive material after providing the first conductive material; and
annealing the first conductive material prior to providing the second conductive material.

13. The method of claim 9, wherein the entire exposed area of the conductive feature is smaller than 7 μm².

14. The method of claim 9, wherein a maximum grain size of the second conductive material, in a linear lateral dimension, after directly bonding the first element and the second element is smaller than 30% of the linear lateral dimension of the conductive feature.

15. The method of claim 9, wherein a maximum linear lateral grain size of the second conductive material at the bonding surface after directly bonding the first element and the second element is smaller than 2 μm.

16. A method of forming a conductive feature in a substrate for direct hybrid bonding, the method comprising:
depositing a first conductive material by a first deposition process comprising plating under conditions for forming a first average grain size;
depositing a second conductive material by a second deposition process different from the first deposition process without increasing impurity levels relative to the first deposition process, wherein the second deposition process forms a second average grain size smaller than the first deposition process; and
preparing a bonding surface including the second conductive material and a nonconductive surface for direct hybrid bonding.

17. The method of claim 16, wherein an impurity level of the first conductive material being equal to or greater than the second conductive material.

18. The method of claim 16, wherein the second deposition process is a process that suppresses grain growth without introducing less than 20 parts per million (ppm) of impurities at grain boundaries of the second conductive material.

19. The method of claim 16, wherein the first deposition process comprises a plating process and the second deposition process comprises a vapor deposition process.

20. The method of claim 16, wherein the first deposition process comprises plating using a first current density and the second deposition process comprises plating using a second current density higher than the first current density.
